(19) United States
(12) Patent Application Publication
(10) Pub. No.: US 2026/0213492 A1
(43) Pub. Date: Jul. 23, 2026

(54) Gas Filled Hollow-Core Silicon Spiral Waveguide Photonic Chip Laser

(71) Applicant: LobOptics Inc., Glendale, CA (US)

(72) Inventors: Farzin Beygi Azar Aghbolagh, Anaheim, CA (US); Arin Abed, Glendale, CA (US)

(21) Appl. No.: 19/030,969

(22) Filed: Jan. 17, 2025

(51) Int. Cl. H01S 5/10; H01S 5/00; H01S 5/02253; H01S 5/024; H01S 5/11

(52) U.S. Cl. CPC H01S 5/101; H01S 5/0014; H01S 5/02253; H01S 5/02415; H01S 5/1017; H01S 5/11

(57) ABSTRACT

The gas-filled hollow-core silicon spiral waveguide photonic chip laser combines optically pumped gas laser technology with semiconductor technology, offering a compact, efficient, and scalable platform for mid-IR laser generation. Its core feature is a hollow-core silicon spiral waveguide filled with molecular gases that absorb pump light to generate mid-IR emission. The system supports versatile pump laser configurations, including external fiber-based or free-space coupling, or integration of a diode laser chip within the same package for enhanced miniaturization. Operating in single-pass Amplified Spontaneous Emission (ASE) mode, it eliminates the need for feedback mirrors. Alternatively, external mirrors or integrated Distributed Bragg Reflectors (DBRs) can form a cavity, enabling feedback operation for enhanced coherence and efficiency. Thermal management is achieved through a Thermo-Electric Cooler, while gas pressure is monitored and adjusted with optional sensors and vacuum micro valves. This adaptable system serves applications in spectroscopy, environmental monitoring, diagnostics, and defense.

### BACKGROUND

The invention relates to lasers and laser systems, particularly a gas filled hollow-core silicon spiral waveguide photonic chip laser.

Mid-infrared (mid-IR) lasers are critical for a wide range of applications, including molecular spectroscopy, environmental monitoring, medical diagnostics, free-space communication, and defense. For example, mid-IR lasers enable precise detection and analysis of gases and chemicals in spectroscopy, which is vital for monitoring air quality and detecting hazardous substances. In medical diagnostics, these lasers support non-invasive glucose monitoring and other biochemical analyses. Similarly, in defense, mid-IR lasers play a key role in infrared countermeasures and remote sensing.

Several technologies exist for generating mid-IR coherent lasers, including gas lasers, fiber lasers, and quantum cascade lasers (QCLs). For example, gas filled hollow-core fiber lasers are used in various applications where the technology combines gas lasers and hollow-core fibers. Gas filled hollow-core fiber lasers have been successfully demonstrated using various molecular gases, where the gases are optically pumped in the near-infrared (IR) range to produce mid-IR laser light. These lasers utilize the hollow core of the fiber to confine both the pump and laser fields, enabling efficient laser operation even in the presence of significant optical losses.

### SUMMARY

In accordance with an aspect, the invention features a gas filled hollow-core silicon spiral waveguide photonic chip laser, including a hollow-core silicon spiral waveguide photonic chip located inside of a package, an output lens parallel to and located behind an output opening of the hollow-core silicon spiral waveguide photonic chip, a spectral filter parallel to and located behind the output lens, and an output optical window parallel to and located behind the spectral filter.

The laser also includes a subcarrier located underneath the hollow-core silicon spiral waveguide photonic chip, a temperature sensor located on the hollow-core silicon spiral waveguide photonic chip, and a thermo-electric cooler located within the package and underneath the subcarrier.

Wherein the laser's hollow-core silicon spiral waveguide photonic chip is attached to the subcarrier using a thermally conductive epoxy, the subcarrier is attached to the thermo-electric cooler using a thermally conductive epoxy, and the thermo-electric cooler is attached to the bottom inner surface of the package using a thermally conductive epoxy.

Wherein the laser's output lens and the spectral filter are attached to the subcarrier using an adhesive.

The laser also includes gas molecules as a laser gain medium interspersed within the package and within cavity of the hollow-core silicon spiral waveguide photonic chip, temperature sensor electrical leads, and thermo-electric cooler electrical leads.

In some embodiments, the laser also includes an input lens parallel to and located in front of an input opening of the hollow-core silicon spiral waveguide photonic chip, wherein the input lens is attached to the subcarrier using the adhesive, and a tunable pump laser configured to deliver pump laser beam into the package

In some embodiments, the laser also includes collimating optics integrated at the input section of the package, and an output fiber delivering the laser beam from the tunable pump laser into the package through the collimating optics.

In some embodiments, the laser also includes a gas pressure sensor located on the subcarrier, pressure sensor electrical leads, and a vacuum micro valve integrated into the package.

In other embodiments, the laser also includes an input optical window located in front of the input lens wherein the tunable pump laser beam enters into the package through the input optical window.

In other embodiments, the laser also includes a gas pressure sensor located on the subcarrier, pressure sensor electrical leads, and a vacuum micro valve integrated into the package.

In yet other embodiments, the laser also includes an input mirror parallel to and located in between the input lens and the input opening of the hollow-core silicon spiral waveguide photonic chip, wherein the input mirror is attached to the subcarrier using the adhesive, and an output mirror parallel to and located in between the output lens and the output opening of the hollow-core silicon spiral waveguide photonic chip, wherein the output mirror is attached to the subcarrier using the adhesive.

In yet other embodiments, the laser also includes collimating optics integrated at the input section of the package, and an output fiber delivering the laser beam from the tunable pump laser into the package through the collimating optics.

In yet other embodiments, the laser also includes a gas pressure sensor located on the subcarrier; pressure sensor electrical leads; and a vacuum micro valve integrated into the package.

In further embodiments, the laser also includes an input optical window located in front of the input lens wherein the tunable pump laser enters into the package through the input optical window.

In further embodiments, the laser also includes a gas pressure sensor located on the subcarrier, pressure sensor electrical leads, and a vacuum micro valve integrated into the package.

In alternate embodiments, the laser also includes an input DBR mirror integrated within the input opening of the hollow-core silicon spiral waveguide, and an output DBR mirror integrated within the output opening of the hollow-core silicon spiral waveguide.

In alternate embodiments, the laser also includes collimating optics integrated at the input section of the package, and an output fiber delivering the laser beam from the tunable pump laser into the package through the collimating optics.

In alternate embodiments, the laser also includes a gas pressure sensor located on the subcarrier, pressure sensor electrical leads, and a vacuum micro valve integrated into the package.

In other alternate embodiments, the laser also includes an input optical window located in front of the input lens wherein the tunable pump laser enters into the package through the input optical window.

In other alternate embodiments, the laser also includes a gas pressure sensor located on the subcarrier, pressure sensor electrical leads, and a vacuum micro valve integrated into the package.

In different embodiments, the laser also includes a collimating lens parallel to and located in front of an input opening of the hollow-core silicon spiral waveguide photonic chip, wherein the collimating lens is attached to the subcarrier using the adhesive, an input lens parallel to and located in between the collimating lens and the front of the input opening of the hollow-core silicon spiral waveguide photonic chip, wherein the input lens is attached to the subcarrier using the adhesive, a diode laser chip located in front of the collimating lens, wherein the diode laser chip is incorporated unto a sub-mount, wherein the sub-mount is attached to the subcarrier using a thermally conductive epoxy, and diode laser chip electrical leads.

In different embodiments, the laser also includes a gas pressure sensor located on the subcarrier, pressure sensor electrical leads, and a vacuum micro valve integrated into the package.

### DESCRIPTION OF THE DRAWINGS

Embodiments in accordance with the present disclosures are shown in the drawings and will be described below with reference to the figures, whereby elements having the same effect have been provided with the same reference numerals. The following is shown:

FIG. 1A depicts an embodiment of a gas filled hollow-core silicon spiral waveguide photonic chip laser;

FIG. 1B depicts a perspective view of the gas filled hollow-core silicon spiral waveguide photonic chip laser detailed in FIG. 1A;

FIG. 2 depicts another embodiment of a gas filled hollow-core silicon spiral waveguide photonic chip laser;

FIG. 3 depicts another embodiment of the gas filled hollow-core silicon spiral waveguide photonic chip laser where a laser diode is integrated into the package;

FIG. 4 depicts another embodiment of the gas filled hollow-core silicon spiral waveguide photonic chip laser where external input and output mirrors are integrated into the package;

FIG. 5 depicts another embodiment of the gas filled hollow-core silicon spiral waveguide photonic chip laser where internal input and output mirrors are integrated into the package;

FIG. 6 depicts another view of the laser detailed in FIGS. 1A and 1B;

FIG. 7 depicts another view of the laser detailed in FIG. 2; and

FIG. 8 depicts another view of the laser detailed in FIG. 3.

### DESCRIPTION OF THE REFERENCES

To facilitate a comprehensive understanding of the Gas Filled Hollow-Core Silicon Spiral Waveguide Photonic Chip Laser, the following list is not limited but enumerates the reference numerals used throughout the description and drawings.

The list is as follows:
1. Tunable pump laser 101/201/401/501
2. Output fiber 102/402/502/602
4. Collimating optics 104/404/504/604
5. Gas molecules 105/405/505
6. Input lens 106/206/406/506
7. Adhesive 107/407/507
8. Subcarrier 108/308/408/508
9. Temperature sensor 109/409/509
10. Hollow-core silicon spiral waveguide photonic chip 110/310/410/510
11. Thermally conductive epoxy 111/311/411/511
12. Gas pressure sensor (optional) 112/412/512
13. Output lens 113/413/513
14. Spectral filter 114/414/514
15. Thermo-Electric Cooler (TEC) 115/415/515
16. Output optical window 116/416/516/616/716/816
17. Optical detector (optional) 117/417/517
18. Vacuum micro valve (optional) 118/418/518
19. Package 119/319/419/519/619/719/819
20. Temperature sensor electrical leads 120/420/520/620/720/820
21. TEC electrical leads 121/421/521/621/721/821
22. Pressure sensor electrical leads (optional) 122/422/522/622/722/822
23. Input optical window 202/704
24. Sub-mount 324
25. Diode laser chip 325
26. Diode laser chip electrical leads 323/823
27. Collimating lens 326
28. Input mirror 425
29. Output mirror 426
30. Input DBR mirror 525
31. Output DBR mirror 526

### DESCRIPTION

As used throughout this disclosure, the word “may” is used in a permissive sense (i.e., meaning having the potential to), rather than the mandatory sense (i.e., meaning must). Similarly, the words “include”, “including”, and “includes” mean including but not limited to.

The phrases “at least one”, “one or more”, and “and/or” are open-ended expressions that are both conjunctive and disjunctive in operation. For example, each of the expressions “at least one of A, B and C”, “one or more of A, B, and C”, and “A, B, and/or C” mean all of the following possible combinations: 1) A alone; 2) B alone; 3) C alone; 4) A and B together; 5) A and C together; 6) B and C together; or 7) A, B and C together. Also, as used herein, including in the claims, the term “and/or,” used in connection with a list of items or categories, means one or more of the items or categories in the list, i.e., at least one of the items or categories in the list, but not necessarily all the items in the list and not necessarily one item from each category in the list. As used herein, including in the claims, the term “or,” used in connection with a list of items or categories, means one or more of the items or categories in the list, i.e., at least one of the items or categories in the list, but not necessarily all the items in the list and not necessarily one item from each category in the list. “Or” does not mean “exclusive or,” and “or” does not mean “at least one from each (category).”

Also, all references (e.g., patents, published patent applications, and non-patent literature) that are cited within this document are incorporated herein in their entirety by reference.

Furthermore, the described features, advantages, arid characteristics of any particular embodiment disclosed herein, may be combined in any suitable manner with any of the other embodiments disclosed herein.

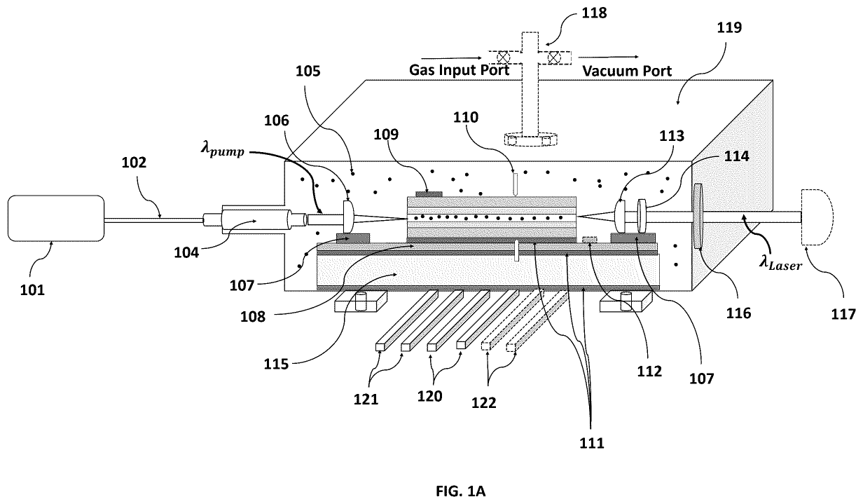

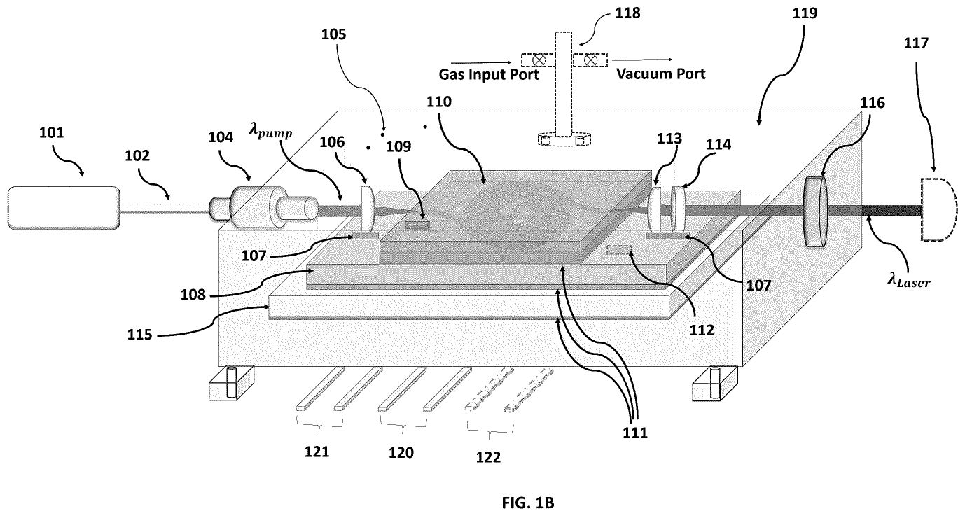

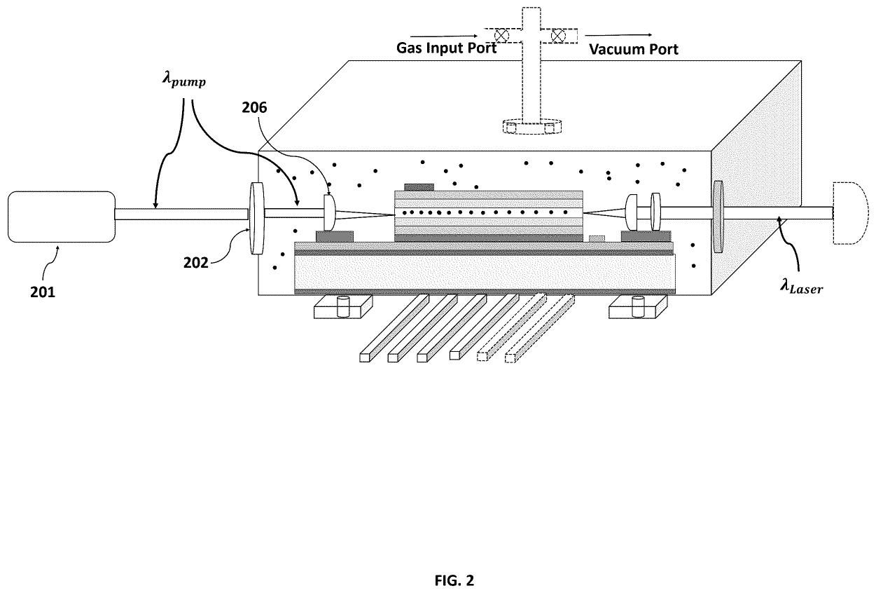

In FIG. 1A, an embodiment of the present laser system is described in a schematic view where the broken lines indicate optional components or features. At the input side of the gas filled hollow-core silicon spiral waveguide photonic chip laser is a tunable pump laser source 101, which generates coherent radiation in the near-IR spectrum. This tunable light source is used to optically excite the gas molecules confined within the hollow core of silicon spiral waveguide, enabling the generation of mid-IR laser light. This tunable pump laser 101 can be configured in multiple ways to suit various applications. Depending on the specific requirements, the tunable pump laser 101 can be a pulsed laser or a continuous wave (CW) laser. Additionally, the tunable pump laser 101 can be configured to deliver its output either through an optical fiber 102 or via free-space propagation (see FIG. 2. below), depending on the system's design requirements, providing flexibility in how the laser is integrated into different configurations.

The tunable pump laser 101 may emit laser light through the output fiber 102, which serves to guide the light to the subsequent stage of the system—specifically the collimating optics 104. The output fiber 102 is optically coupled to the collimating optics 104. The collimating optics 104 allows the tunable pump laser 101's beam to remain collimated, maintaining a parallel path as it is directed into the subsequent stages of the system.

The collimating optics 104 deliver the pump laser light into the package 119. The package includes various components for generating mid-IR laser light. The package 119 can be a ceramic housing, with supporting electro-optical components. The package 119 contains a chamber that is evacuated and filled with gas molecules 105, where the gas molecules 105 are also found inside the hollow-core silicon spiral waveguide photonic chip 110, serving as the laser gain medium. The package 119 is hermetically sealed to protect these components and ensure stable and reliable laser operation.

Once the tunable pump laser 101 light is coupled into the gas filled hollow-core silicon spiral waveguide photonic chip 110 by the input lens 106, it propagates through the hollow-core silicon spiral waveguide photonic chip 110, where it is absorbed by the gas molecules 105. Depending on the type of gas and the spectral region of interest, the pump and gain transitions can involve electronic, vibrational, rotational states, or combinations thereof.

The design of the hollow-core silicon spiral waveguide photonic chip 110 can be optimized to minimize propagation losses at both the tunable pump laser 101 and lasing wavelengths, depending on the gas molecules 105 used as the gain medium. Gas molecules 105 such as carbon monoxide (CO), carbon dioxide (CO₂), acetylene (C₂H₂), hydrogen cyanide (HCN), nitrous oxide (N₂O), hydrogen bromide (HBr), deuterium fluoride (DF), hydrogen fluoride (HF) and many other gases or gas mixtures are effective lasing media in the hollow-core silicon spiral waveguide photonic chip 110 due to their strong absorption and emission properties in the infrared spectrum.

Thereafter, the tunable pump laser 101 light, collimated by the collimating optics 104 inside the package 119, is directed into the input lens 106, which focuses the beam before it proceeds to the next stage at the input opening of the hollow-core silicon spiral waveguide photonic chip 110. The input lens 106 is secured inside the package 119 using an adhesive 107, chosen for its ability to withstand varying pressures and thermal shifts while maintaining a permanent bond. As a result, the structural integrity of the input lens 106 depends on the properties of the adhesive 107 used within the package 119. The input lens 106 is affixed unto the subcarrier 108 via the adhesive 107. The subcarrier 108 is a uniform slab designed with certain thermo-mechanical properties that serves as a mounting base for the rest of the system and components within the package 119.

Sitting on top of the subcarrier 108 is the hollow-core silicon spiral waveguide photonic chip 110. The hollow-core silicon spiral waveguide photonic chip 110 is aligned with respect to the input lens 106 to enable efficient coupling of the tunable pump laser 101 into the hollow-core silicon spiral waveguide photonic chip 110 filled with gas molecules 105. The hollow-core silicon spiral waveguide photonic chip 110 guides both the tunable pump laser 101 light and the generated mid-IR emission through its hollow waveguide structure, where the gas molecules 105 act as the laser gain medium.

Utilizing the hollow-core silicon spiral waveguide photonic chip 110 offers many advantages: its compact form factor results in a more compact and smaller system compared to traditional gas filled hollow-core fiber lasers, while its superior thermal conductivity enhances overall efficiency. The hollow-core silicon spiral waveguide photonic chip 110 also offers significant advantages in terms of production and scalability, making it an ideal choice for large-scale manufacturing and widespread application. The hollow-core silicon spiral waveguide photonic chip 110 design enables the fabrication of a long hollow core waveguide in a significantly smaller form factor.

The hollow-core spiral waveguide design, particularly its length and hollow-core diameter, can be optimized to increase the interaction length between the tunable pump laser 101 and gas molecules 105, resulting in low pump laser threshold power and energy. A gas filled hollow-core silicon spiral waveguide photonic chip 110 can operate based on population inversion. The size, length, shape, and inner reflective coating of the hollow-core silicon spiral waveguide photonic chip 110 can be optimized to minimize propagation loss at both pump and lasing emission wavelengths. The hollow-core silicon spiral waveguide photonic chip 110, which serves as the host structure for the gas molecules 105, can be packaged in various configurations.

In yet another embodiment, the packaging 119 can incorporate an input optical window for use with a free-space pump laser (discussed under FIG. 2.).

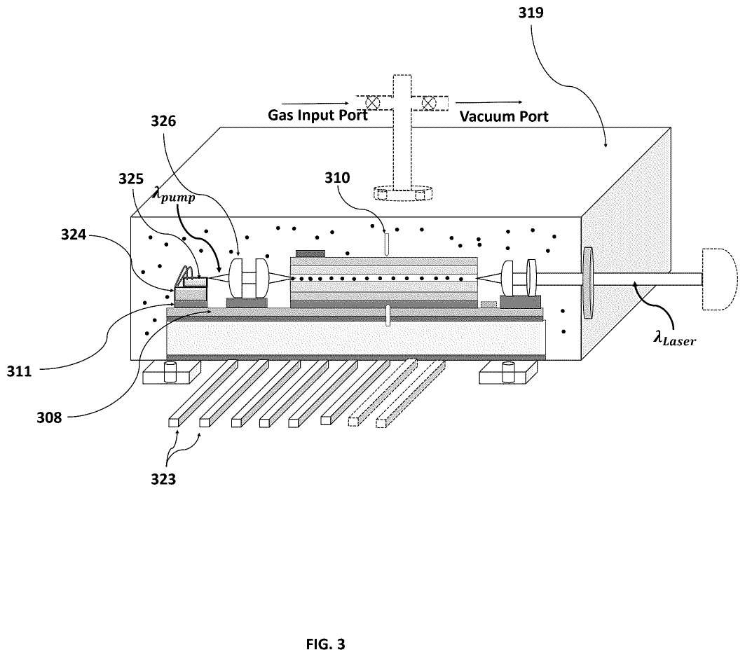

In yet another embodiment, the tunable pump laser 101 can also be integrated within the same package 119 (as discussed under FIG. 3). A semiconductor III-V diode laser chip emitting in the near-IR range can be used inside the package 119 and be aligned with the hollow-core silicon spiral waveguide photonic chip 110 to serve as the tunable pump laser 101 source.

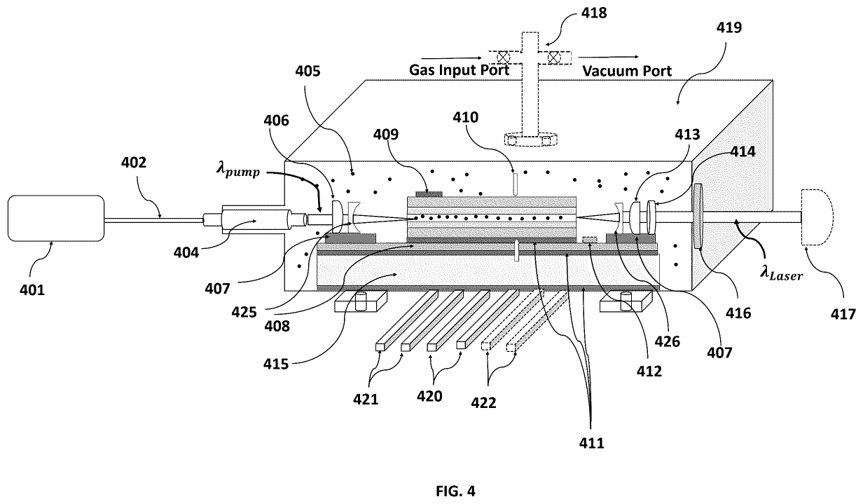

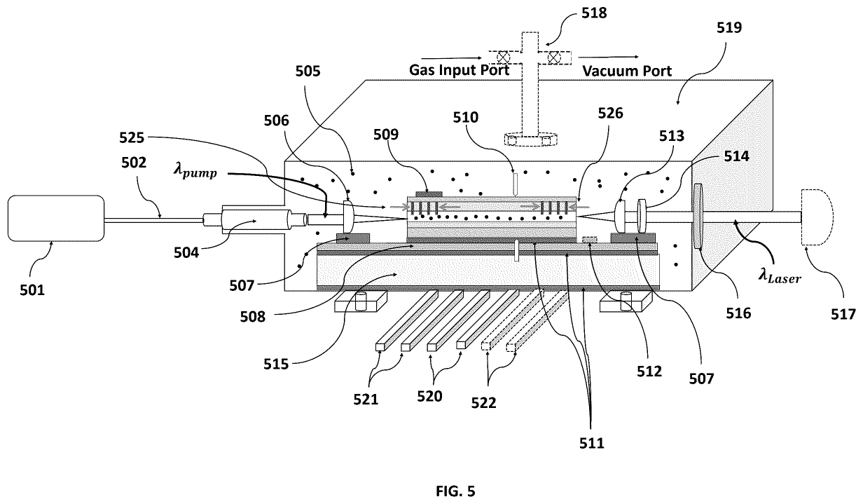

Mirrors can be positioned at the input and output openings of the hollow-core silicon spiral waveguide photonic chip 110 to form a laser cavity (as discussed in FIG. 4), or the configuration can operate without cavity mirrors, relying on Amplified Spontaneous Emission (ASE) (as discussed under FIG. 1-3). Additionally, the cavity mirrors can be integrated directly within the hollow-core silicon spiral waveguide photonic chip 110 itself (as discussed under FIG. 5). Distributed Bragg Reflectors (DBRs) can be designed and fabricated inside the hollow-core silicon spiral waveguide photonic chip 110 to serve as cavity mirrors, further enhancing the flexibility and functionality of the laser system.

Once the tunable pump laser 101 light is coupled to the hollow-core silicon spiral waveguide photonic chip 110 by the input lens 106, the tunable pump laser 101 light propagates through the gas filled hollow-core silicon spiral waveguide photonic chip 110, where it is absorbed by the gas molecules 105, exciting the gas molecules 105 to a different electrical, rotational, or vibrational energy levels. This process creates heat, which is monitored using a temperature sensor 109 attached to the hollow-core silicon spiral waveguide photonic chip 110. Moreover, to enhance thermal dissipation, a layer of thermally conductive epoxy 111 is applied beneath the hollow-core silicon spiral waveguide photonic chip 110 and another layer of thermally conductive epoxy 111 under the subcarrier 108.

The entire hollow-core silicon spiral waveguide photonic chip 110 is then affixed unto the subcarrier 108, which in turn is affixed unto a Thermo-Electric Cooler (TEC) 115 such as a Peltier module. The purpose of a TEC 115 is to cool down the hollow-core silicon spiral waveguide photonic chip 110 and keep it at a stable temperature to ensure laser efficiency and stability. The temperature sensor 109 provides feedback to the TEC 115, enabling regulation of the hollow-core silicon spiral waveguide photonic chip 110 temperature to maintain the desired set point value. The TEC 115 is finally affixed within the bottom inner surface of the package 119 using the thermally conductive epoxy 111 material described above.

At the output opening of the hollow-core silicon spiral waveguide photonic chip 110 are located additional components such as the output lens 113. The output lens 113 is transparent at the lasing mid-IR emission wavelength and can be used to collimate the laser beam as it exits the hollow-core silicon spiral waveguide photonic chip 110. The idea is to align and direct the emitted mid-IR laser beam towards later stage of the system.

Following the output lens 113, is a spectral filter 114 which is designed to absorb the pump wavelength as there is some residual pump light left in the output emission beam. The spectral filter 114 thus allows only lasing mid-IR emission wavelength to pass through to the next stage of the system.

Thereafter, the emitted mid-IR laser beam can exit the package 119 through an optical window 116. In some embodiments, there may be an optical detector 117 after the optical window 116, in order to measure the wavelength, power, energy or other parameters of the emitted mid-IR laser beam. Thus, a monochromator or optical spectrum analyzer, as a form of an optical detector 117, can be employed to determine the lasing emission wavelength. The gain of the laser, depending on the specific gas molecules 105 used, may be sufficient to allow operation without the need for an optical feedback cavity, even in the presence of significant hollow-core silicon spiral waveguide photonic chip 110 losses at the lasing wavelength. As a result, the laser can effectively operate without the incorporation of mirrors to form a cavity.

In order for the package 119 to operate, there are electrical lead lines that supply power and are used to monitor the various components within the package 119. For example, the temperature sensor 109 has its dedicated temperature sensor electrical leads 120 for its operational needs. Likewise, the TEC 115 has its own TEC electrical leads 121 to maintain its operations. In some embodiments, where a gas pressure sensor 112 is affixed near the hollow-core silicon spiral waveguide photonic chip 110, there are dedicated pressure sensor electrical leads 122 used to operate the pressure sensor 112.

In some embodiments, the package 119 may include a vacuum micro valve 118 that allows for precise adjustments of the gas pressure, enabling the characterization of the laser output at different gas pressures. A gas pressure sensor 112, mounted on the subcarrier 108, will continuously monitor the gas pressure near the hollow-core silicon spiral waveguide photonic chip 110. The tunable laser pump 101 can also be tuned to match the absorption resonance of the gas molecules 105. The vacuum micro valve 118 has two ports that allow for adjustment of the pressure of the gas molecules 105 contained within the package 119. One port is used to input addition gas molecules 105 into the package 119 and another port for vacuuming out excess gas molecules 105 from the package 119.

In FIG. 1B, the embodiment of FIG. 1A is depicted showing the same components, relative to one another, and a clear view of the spiral waveguide. All references discussed above under FIG. 1 are incorporated herein to fully describe FIG. 1B.

In FIG. 2, another embodiment of the present system is described in a schematic view, where the broken lines indicate optional components or features.

In this configuration, the tunable pump laser 201 outputs an already collimated laser beam into an input optical window 202 positioned in an input section of the package 119. Thereafter, the beam is directed to the input lens 206 which focuses the beam into the rest of the package 119 as described in FIG. 1A.

The rest of the package 119 of FIG. 2 mimics the laser described in FIG. 1A. This configuration allows for coupling of free-space output pump lasers into the package 119. As an example, for applications requiring higher output laser power, the tunable pump laser 201 can be upgraded to a free-space output configuration pump laser. This modification is useful for scenarios where a higher input pump laser power/energy is needed, as it eliminates the risk of fiber damage associated with the lower damage threshold of silica glass for the fiber-based pump lasers. By switching to a free-space output pump laser, the system can accommodate higher input power levels. To implement this, the package 119 design may be adjusted by replacing the collimator optics 104 with an input optical window 202.

In FIG. 3, another embodiment of the gas filled hollow-core silicon spiral waveguide photonic chip laser is depicted where a diode laser chip 325 is integrated into the package 319 itself. In this configuration, further miniaturization can be achieved. This approach involves incorporating the diode laser chip 325, such as a semiconductor III-V diode laser chip onto a sub-mount 324 into the package 319. The sub-mount 324 is then affixed unto the subcarrier 308 using a thermally conductive epoxy 311. The diode laser chip 325 is placed in front of a collimating lens 326, ensuring that the diode laser chip 325 beam is properly collimated and aligned with the hollow-core silicon spiral waveguide photonic chip 310. In order to operate the diode laser chip 325, diode laser chip electrical leads 323 are incorporated into the package 319. The rest of the gas filled hollow-core silicon spiral waveguide photonic chip laser mimics the laser described in FIGS. 1A and 1B.

This integration reduces the overall footprint of the device, enhance alignment precision, and minimize potential losses associated with coupling tunable pump laser light when the tunable pump laser is external and located outside the package 319.

In FIG. 4, another embodiment of the gas filled hollow-core silicon spiral waveguide photonic chip laser is depicted where two additional mirrors are incorporated into the package 419. An input mirror 425 is installed in between the input lens 406 and the input opening of the hollow-core silicon spiral waveguide photonic ship 410. Moreover, an output mirror 426 is installed in between the output opening of the hollow-core silicon spiral waveguide photonic ship 410 and the output lens 413. These external input mirror 425 and the output mirror 426 are affixed unto the subcarrier 408 using an adhesive 407. The rest of the gas filled hollow-core silicon spiral waveguide photonic chip laser mimics the laser described in FIGS. 1A and 1B.

With this external mirror configuration however, the input mirror 425 and the output mirror 426, form a laser cavity for enhanced lasing performance. The input mirror 425, located at the hollow-core silicon spiral waveguide photonic chip's 410 input side, is transparent to the laser light generated by the tunable pump laser 401. This allows a more efficient coupling of the laser light into the gas filled hollow core silicon spiral waveguide photonic chip but highly reflective at the generated mid-IR laser wavelength. Moreover, this ensures that the generated mid-IR light is reflected back into the hollow-core silicon spiral waveguide photonic chip 410 to sustain the lasing process. The output mirror 426, positioned at the hollow-core silicon spiral waveguide photonic chip's 410 output, is partially reflective at the mid-IR generated wavelength. It reflects a portion of the generated mid-IR laser light back into the hollow-core silicon spiral waveguide photonic chip 410 for amplification, while allowing the remaining light to exit as the laser output.

Adding these mirrors can offer advantages over the ASE based systems (FIGS. 1A, 1B, 2, and 3). These advantages can lead to enhance coherence, higher laser output power, improved laser efficiency, and superior beam quality.

In FIG. 5, another embodiment of the gas filled hollow-core silicon spiral waveguide photonic chip laser is depicted where Distributed Bragg Reflectors (DBRs)/internal mirrors 525 and 526 are integrated within the hollow-core silicon spiral waveguide 510 as part of the semiconductor fabrication process. The DBRs serve the same purpose as the external mirrors discussed above under FIG. 4, but instead, they are part of the structure of the hollow-core silicon spiral waveguide photonic chip 510 itself.

The input DBR mirror 525 situated within the input part of the hollow-core silicon spiral waveguide 510 is transparent to pump light but highly reflective at the mid-IR wavelength to reflect generated light back into the cavity of the hollow-core silicon spiral waveguide photonic chip 510. Likewise, the output DBR mirror 526 situated within the output part of the hollow-core silicon spiral waveguide photonic chip 510 is partially reflective at the mid-IR wavelength, reflecting some light back for amplification while allowing the remainder to exit as laser output.

The rest of the gas filled hollow-core silicon spiral waveguide photonic chip laser mimics the laser described in FIGS. 1A and 1B.

Some advantages of this configuration are reduction of components by eliminating external mirrors. Also improving alignment and coupling within the waveguide to reduce losses and enhance efficiently. Reducing the assembly of the final configuration and aiding in miniaturization.

In further embodiments that are tailored to specific applications requiring extended operation or higher power outputs, additional thermal management solutions can be implemented. For instance, integrating advanced thermal interface materials (TIMs) between the hollow-core silicon spiral waveguide photonic chip 110, subcarrier 108, and TEC 115 may further improve heat dissipation, maintaining optimal operating temperatures and ensuring the long-term reliability of the device.

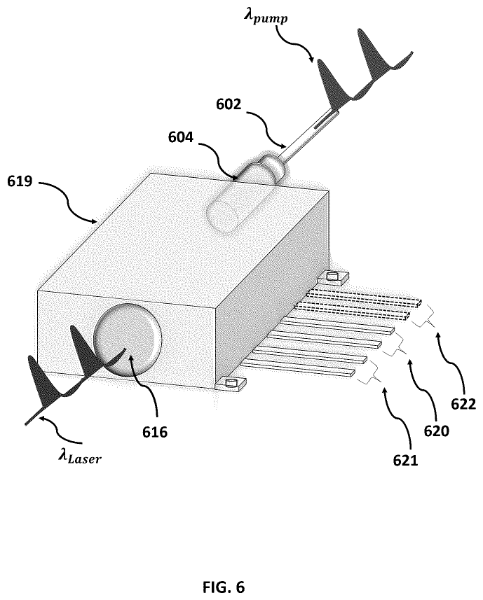

FIG. 6 depicts the laser as described in FIGS. 1A and 1B, for the case where a fiber-based tunable pump laser is utilized. The pump laser light propagates through the output fiber 602, which is coupled to the collimating optics 604. The collimating optics 604 directs the pump laser light into the package 619. The package 619 includes electrical lead lines, temperature sensor electrical leads 620, TEC electrical leads 621, and, in some embodiments, pressure sensor electrical leads 622. The generated mid-IR output laser beam exits the package 619 through the output optical window 616.

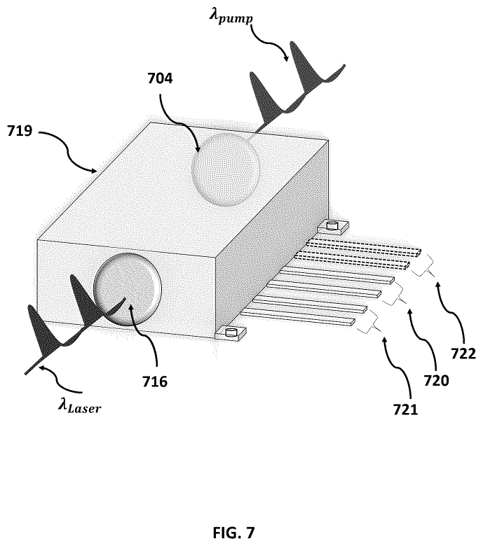

FIG. 7 depicts the laser as described in FIG. 2, for the case where a free-space tunable pump laser is utilized. The collimated tunable pump laser light propagates through free space before entering the package 719 through the input optical window 704. Inside the package 719 the generated mid-IR output laser beam exits the package 719 through the output optical window 716. The package 719 includes electrical lead lines such as the temperature sensor electrical leads 720, the TEC electrical leads 721, and, in some embodiments, the pressure sensor electrical leads 722.

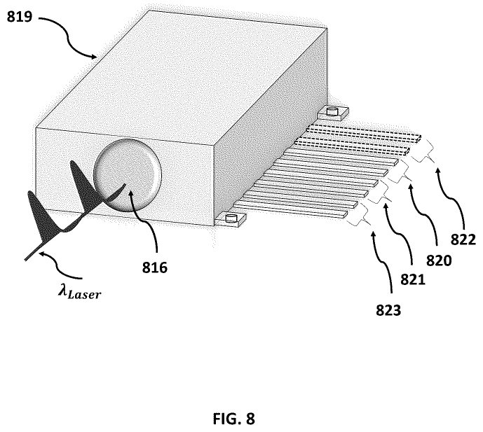

FIG. 8 depicts the laser as described in FIG. 3, for the case where a diode laser chip 325 is built into the package 819. The diode laser chip 325 is controlled by the diode laser chip electrical leads 823. Inside the package 819, the generated mid-IR output laser beam exits the package 819 through the output optical window 816. The package 819 also includes electrical lead lines such as the temperature sensor electrical leads 820, the TEC electrical leads 821, the diode laser chip electrical leads 823, and, in some embodiments, the pressure sensor electrical leads 822.

Although the present disclosure has been described in considerable detail with reference to certain embodiments thereof, other embodiments are possible. To cater to a broader range of applications, the embodiments here can be designed with scalability in mind. Modular components, such as interchangeable hollow-core silicon spiral waveguide photonic chips 110 with varying lengths, shapes, size, and inner surface coatings, can be developed to tailor the laser's performance to specific needs. This flexibility allows the embodiments to be adapted for different industries, from telecommunications to medical diagnostics, and defense applications. Therefore, the scope of the appended claims should not be limited to the description of the embodiments contained herein.

For example, FIGS. 1A and 1B can be configured to adapt components from other embodiments such that it works as an ASE without mirrors or operating with mirrors either externally incorporated or with integration of DBRs. Likewise, FIG. 2 can be configured to adapt components from other embodiments such that it works as an ASE without mirrors or operating with mirrors either externally incorporated or with integration of DBRs. Finally, FIG. 3 can be configured to adapt components from other embodiments such that it works as an ASE without mirrors or operating with mirrors either externally incorporated or with integration of DBRs.

What is claimed is:

1. A gas filled hollow-core silicon spiral waveguide photonic chip laser comprising:
a hollow-core silicon spiral waveguide photonic chip located inside of a package;
an output lens parallel to and located behind an output opening of the hollow-core silicon spiral waveguide photonic chip;
a spectral filter parallel to and located behind the output lens; and
an output optical window parallel to and located behind the spectral filter.

2. The gas filled hollow-core silicon spiral waveguide photonic chip laser of claim 1, further comprising:
a subcarrier located underneath the hollow-core silicon spiral waveguide photonic chip;
a temperature sensor located on the hollow-core silicon spiral waveguide photonic chip; and
a thermo-electric cooler located within the package and underneath the subcarrier.

3. The gas filled hollow-core silicon spiral waveguide photonic chip laser of claim 2, wherein:
the hollow-core silicon spiral waveguide photonic chip is attached to the subcarrier using a thermally conductive epoxy;
the subcarrier is attached to the thermo-electric cooler using a thermally conductive epoxy; and
the thermo-electric cooler is attached to the bottom inner surface of the package using a thermally conductive epoxy.

4. The gas filled hollow-core silicon spiral waveguide photonic chip laser of claim 3, wherein the output lens and the spectral filter are attached to the subcarrier using an adhesive.

5. The gas filled hollow-core silicon spiral waveguide photonic chip laser of claim 4, further comprising:
gas molecules as a laser gain medium interspersed within the package and within cavity of the hollow-core silicon spiral waveguide photonic chip;
temperature sensor electrical leads; and
thermo-electric cooler electrical leads.

6. The gas filled hollow-core silicon spiral waveguide photonic chip laser of claim 5, further comprising:
an input lens parallel to and located in front of an input opening of the hollow-core silicon spiral waveguide photonic chip, wherein the input lens is attached to the subcarrier using the adhesive; and
a tunable pump laser configured to deliver pump laser beam into the package.

7. The gas filled hollow-core silicon spiral waveguide photonic chip laser of claim 6, further comprising:
collimating optics integrated at the input section of the package; and
an output fiber delivering the laser beam from the tunable pump laser into the package through the collimating optics.

8. The gas filled hollow-core silicon spiral waveguide photonic chip laser of claim 7, further comprising:
a gas pressure sensor located on the subcarrier;
pressure sensor electrical leads; and
a vacuum micro valve integrated into the package.

9. The gas filled hollow-core silicon spiral waveguide photonic chip laser of claim 6, further comprising an input optical window located in front of the input lens wherein the tunable pump laser beam enters into the package through the input optical window.

10. The gas filled hollow-core silicon spiral waveguide photonic chip laser of claim 9, further comprising:
a gas pressure sensor located on the subcarrier;
pressure sensor electrical leads; and
a vacuum micro valve integrated into the package.

11. The gas filled hollow-core silicon spiral waveguide photonic chip laser of claim 6, further comprising:
an input mirror parallel to and located in between the input lens and the input opening of the hollow-core silicon spiral waveguide photonic chip, wherein the input mirror is attached to the subcarrier using the adhesive; and
an output mirror parallel to and located in between the output lens and the output opening of the hollow-core silicon spiral waveguide photonic chip, wherein the output mirror is attached to the subcarrier using the adhesive.

12. The gas filled hollow-core silicon spiral waveguide photonic chip laser of claim 11, further comprising:
collimating optics integrated at the input section of the package; and
an output fiber delivering the laser beam from the tunable pump laser into the package through the collimating optics.

13. The gas filled hollow-core silicon spiral waveguide photonic chip laser of claim 12, further comprising:
a gas pressure sensor located on the subcarrier;
pressure sensor electrical leads; and
a vacuum micro valve integrated into the package.

14. The gas filled hollow-core silicon spiral waveguide photonic chip laser of claim 11, further comprising an input optical window located in front of the input lens wherein the tunable pump laser enters into the package through the input optical window.

15. The gas filled hollow-core silicon spiral waveguide photonic chip laser of claim 14, further comprising:
a gas pressure sensor located on the subcarrier;
pressure sensor electrical leads; and
a vacuum micro valve integrated into the package.

16. The gas filled hollow-core silicon spiral waveguide photonic chip laser of claim 6, further comprising:
an input DBR mirror integrated within the input opening of the hollow-core silicon spiral waveguide; and
an output DBR mirror integrated within the output opening of the hollow-core silicon spiral waveguide.

17. The gas filled hollow-core silicon spiral waveguide photonic chip laser of claim 16, further comprising:
collimating optics integrated at the input section of the package; and
an output fiber delivering the laser beam from the tunable pump laser into the package through the collimating optics.

18. The gas filled hollow-core silicon spiral waveguide photonic chip laser of claim 17, further comprising:
a gas pressure sensor located on the subcarrier;
pressure sensor electrical leads; and
a vacuum micro valve integrated into the package.

19. The gas filled hollow-core silicon spiral waveguide photonic chip laser of claim 16, further comprising an input optical window located in front of the input lens wherein the tunable pump laser enters into the package through the input optical window.

20. The gas filled hollow-core silicon spiral waveguide photonic chip laser of claim 19, further comprising:
a gas pressure sensor located on the subcarrier;
pressure sensor electrical leads; and
a vacuum micro valve integrated into the package.

21. The gas filled hollow-core silicon spiral waveguide photonic chip laser of claim 5, further comprising:
a collimating lens parallel to and located in front of an input opening of the hollow-core silicon spiral waveguide photonic chip, wherein the collimating lens is attached to the subcarrier using the adhesive;
an input lens parallel to and located in between the collimating lens and the front of the input opening of the hollow-core silicon spiral waveguide photonic chip, wherein the input lens is attached to the subcarrier using the adhesive;
a diode laser chip located in front of the collimating lens, wherein the diode laser chip is incorporated unto a sub-mount, wherein the sub-mount is attached to the subcarrier using a thermally conductive epoxy; and
diode laser chip electrical leads.

22. The gas filled hollow-core silicon spiral waveguide photonic chip laser of claim 21, further comprising:
a gas pressure sensor located on the subcarrier;
pressure sensor electrical leads; and
a vacuum micro valve integrated into the package.
